(19) United States
(12) Patent Application Publication
(10) Pub. No.: US 2022/0002899 A1
(43) Pub. Date: Jan. 6, 2022

(54) HEAT SHIELD FOR MONOCRYSTALLINE SILICON GROWTH FURNACE AND MONOCRYSTALLINE SILICON GROWTH FURNACE

(71) Applicants: Shanghai Institute of Microsystem and Information Technology, Chinese Academy of Sciences, Shanghai (CN); Zing Semiconductor Corporation, Shanghai (CN)

(72) Inventors: Zhongying Xue, Shanghai (CN); Zhan Li, Shanghai (CN); Xing Wei, Shanghai (CN); Minghao Li, Shanghai (CN); Tao Wei, Shanghai (CN); Yun Liu, Shanghai (CN)

(21) Appl. No.: 17/137,339

(22) Filed: Dec. 29, 2020

(30) Foreign Application Priority Data
Jul. 1, 2020 (CN) 202010629650.8

(51) Int. Cl. C30B 15/14; C30B 29/06

(52) U.S. Cl. CPC C30B 15/14; C30B 29/06

(57) ABSTRACT

Disclosed a heat shield and a monocrystalline silicon growth furnace using the same. The heat shield is arranged in an upper portion of a melt crucible in the monocrystalline silicon growth furnace, and comprises a shield wall and a shield bottom provided with a window for pulling melt through. The shield bottom comprises a top layer, a bottom layer and a side wall. The side wall is connected between the top and bottom layers and encloses the window. The bottom layer faces towards a liquid level of the melt, and is designed as a serrated structure. With the serrated structure of the bottom layer of the shield bottom, the external thermal energy can be prevented from being absorbed by the monocrystalline silicon crystal, thereby avoiding excessive thermal compensation on a crystal surface, effectively optimizing longitudinal temperature gradient of the crystal, and improving the radial quality uniformity of a silicon wafer.

### CROSS REFERENCE TO RELATED APPLICATIONS

The present application claims the benefit of Chinese Patent Application No. 202010629650.8 filed on Jul. 1, 2020, the contents of which are incorporated herein by reference in their entirety.

### TECHNICAL FIELD

The present invention relates to the field of manufacturing equipment and design of semiconductors, and in particular to a heat shield for a monocrystalline silicon growth furnace and a monocrystalline silicon growth furnace.

### BACKGROUND

Monocrystalline silicon is a raw material for manufacturing semiconductor silicon devices, and used to manufacture high-power rectifiers, high-power transistors, diodes, switching devices, etc. As molten elemental silicon is cooled, silicon atoms are arranged in a diamond lattice into many crystal nuclei. If these crystal nuclei are grown into crystal grains with the same crystallographic orientation, these crystal grains will combine in parallel and crystallize into monocrystalline silicon. A production method of the monocrystalline silicon usually comprises producing polycrystalline silicon or amorphous silicon first, and then growing rod-shaped monocrystalline silicon from melt by using the Czochralski method or the zone melting method.

Single crystal furnaces are a kind of equipment in which polycrystalline silicon and other polycrystalline materials are melted by a graphite heater in inert gas (mainly nitrogen, or helium) environment, and dislocation-free single crystal are grown through the Czochralski method.

At present, large-size silicon single crystals, especially silicon single crystals with size larger than 12 inches, are mainly prepared through the Czochralski method. The Czochralski method involves melting 99.999999999% high-purity polycrystalline silicon in a quartz crucible, and preparing silicon single crystal using seed crystals through seeding, shouldering, diameter equalizing, and finishing. The thermal field formed by graphite and a heat insulating material is of the most critical in this method, and the design of the thermal field directly determines the quality, process, and energy consumption of the crystal.

In the entire design of the thermal field, the most critical is the design of the thermal shield. Firstly, the design of the heat shield directly affects the vertical temperature gradient at the solid-liquid interface, and the change of the gradient affects the V/G ratio to determine the crystal quality. Secondly, the design of the heat shield affects the horizontal temperature gradient at the solid-liquid interface and control the quality uniformity of the entire silicon wafer. Finally, the design of the heat shield affects heat history of the crystal and control nucleation and growth in the crystal. Therefore, the design of the heat shield is very critical in the process of preparing high-order silicon wafers.

### SUMMARY

In view of the abovementioned problems in the prior art, objectives of the present invention are to provide a heat shield for a monocrystalline silicon growth furnace and a monocrystalline silicon growth furnace, which can control stable thermal compensation on sidewall surface of the monocrystalline silicon crystal and avoid excessive thermal compensation at bottom of the crystal which affects growth of the crystal.

In order to overcome the abovementioned problems in the prior art, the present invention can be achieved by the following technical solutions.

In one aspect, a heat shield for a monocrystalline silicon growth furnace comprising a melt crucible is provided in the present invention, wherein the heat shield is arranged in an upper portion of the melt crucible, and comprises a shield wall and a shield bottom provided with a window for pulling melt through; the shield bottom comprises a top layer, a bottom layer, and a side wall; the side wall is connected between the top layer and the bottom layer and encloses the window; the bottom layer faces towards a liquid level of the melt, and is designed as serrated structure to prevent external thermal energy from being reflected to a sidewall of a monocrystalline silicon crystal.

In a preferred embodiment, a plane where the bottom layer is located is arranged to be parallel to the liquid level of the melt.

In a preferred embodiment, the serrated structure comprises a first row of serrations and a second row of serrations, the first row of serrations is arranged in a direction towards the top layer and the second row of serrations is arranged in a direction away from the top layer, the first row of serrations comprises a plurality of first serrations arranged at first angles, the second row of serrations comprises a plurality of second serrations arranged at second angles, and the first serrations and the second serrations are arranged alternately in sequence.

Alternatively, a plurality of the first angles are not all the same, and a plurality of the second angles are not all the same.

Alternatively, angular bisectors of the first angles are arranged to form acute angles with the liquid level of the melt, and openings of the acute angles are far away from the monocrystalline silicon crystal.

In a preferred embodiment, the first angles and/or the second angles are provided with arcs for transition.

In a preferred embodiment, the top layer, the bottom layer and the side wall enclose an inner space of the shield bottom, which is filled with a heat insulating material.

Alternatively, the heat insulating material comprises carbon fiber felt.

In a preferred embodiment, the top layer and the bottom layer are each provided with a graphite layer.

In another aspect, a monocrystalline silicon growth furnace is provided in the present invention, wherein the monocrystalline silicon growth furnace comprises:

a furnace body comprising a furnace body wall and a cavity surrounded by the furnace body wall;

a melt crucible arranged in the cavity and suitable for containing melt;

a heater arranged in the cavity and around the melt crucible to provide a thermal field for the melt crucible; and

a heat shield for a monocrystalline silicon growth furnace as described above.

By adopting the aforementioned technical solutions, the heat shield for a monocrystalline silicon growth furnace and the monocrystalline silicon growth furnace as described in the present invention have the following beneficial effects:

(1) In the heat shield for a monocrystalline silicon growth furnace and the monocrystalline silicon growth furnace according to the present invention, the bottom layer of the shield bottom is designed as a serrated structure, which can prevent external thermal energy from being absorbed by the monocrystalline silicon crystal, thereby avoiding excessive thermal compensation on the crystal surface, effectively optimizing the longitudinal temperature gradient of the crystal, and improving the radial quality uniformity of a silicon wafer.

(2) In the heat shield for a monocrystalline silicon growth furnace and the monocrystalline silicon growth furnace according to the present invention, the bottom layer of the shield bottom is designed as a serrated structure, which can reflect the external thermal energy into the melt so as to be absorbed by the melt, thereby avoiding a temperature of the liquid level of the melt to fall too fast, ensuring melting state of the melt, and improving effects of crystal pulling.

(3) The heat shield for a monocrystalline silicon growth furnace and the monocrystalline silicon growth furnace according to the present invention can effectively improve process effects by modifying the structure of the shield bottom, and have a better application prospect in the field of semiconductor manufacturing.

### BRIEF DESCRIPTION OF DRAWINGS

In order to more clearly illustrate the technical solutions of the present invention, the accompanying drawings that are used in the description of the embodiments or the prior art will be briefly introduced hereafter. Obviously, the accompanying drawings in the following description are only some embodiments of the present invention, and other accompanying drawings can be obtained based on these drawings by those of ordinary skill in the art without creative work.

FIG. 1 is a schematic diagram showing working environment of a heat shield according to the present invention;

FIG. 2 is a schematic diagram showing a structure of a shield bottom according to an embodiment of the present invention;

FIG. 3 is a schematic structural diagram showing a shield bottom according to a further embodiment of the present invention;

FIG. 4 is a schematic structural diagram showing a shield bottom according to a further embodiment of the present invention;

FIG. 5 is a schematic structural diagram showing a shield bottom according to a further embodiment of the present invention;

FIG. 6 is a schematic structural diagram showing a shield bottom according to a further embodiment of the present invention; and

FIG. 7 is a schematic diagram of a monocrystalline silicon growth furnace according to an embodiment of the present invention.

### LIST OF REFERENCE SIGNS

| | | | |
|---|---|---|---|
| 1 | Heat shield; | 2 | Furnace body; |
| 3 | Melt crucible; | 4 | Heater; |
| 5 | Rotating shaft; | 11 | Shield wall; |
| 12 | Shield bottom; | 21 | Furnace body wall; |
| 121 | Top layer; | 122 | Bottom layer; |
| 123 | Side wall; | 124 | First row of serrations; |
| 125 | Second row of serrations. | | |

### DETAILED DESCRIPTION

Hereafter, the technical solutions according to embodiments of the present invention will be described clearly and thoroughly with reference to accompanying drawings. Obviously, the described embodiments are only part of, not all of, the embodiments of the present invention. Based on the embodiments of the present invention, all other embodiments obtained by those of ordinary skill in the art without creative work shall fall within the protection scope of the present invention.

It should be noted that the terms “first”, “second”, etc. as used in the specification and claims of the present invention and in the above-mentioned drawings are used to distinguish similar objects, and are not intended to define a particular order or sequence. It should be understood that data used with reference to the terms may be interchanged, where appropriate, so that the embodiments of the present invention described herein can be implemented in an order other than those illustrated or described herein. In addition, the terms “comprising”, “including”, “having”, and any variations thereof, are intended to cover non-exclusive inclusions. For example, a process, method, device, product, or apparatus that includes a series of steps or units, not only may include these clearly listed steps or units, but may include other steps or units that are not clearly listed or that are inherent to the process, method, device, product, or apparatus.

### Embodiment 1

During the crystal pulling process of monocrystalline silicon, high requirements on longitudinal and transverse temperature gradients of the crystal are necessary, especially at the bottom of the crystal. Since external thermal energy, such as the thermal energy outside a melt crucible, passes through a gap between a heat shield and the liquid level of melt, and can be absorbed by sidewalls of the crystal after being reflected multiple times, the thermal compensation at heat receiving sites would be higher, which results in changes in the longitudinal temperature gradient of the crystal and is not conducive to rapid pulling of the crystal. On the other hand, small changes in the transverse temperature gradient inside the crystal reduce crystallization efficiency of the crystal, which in turn affects the quality of the entire silicon wafer.

In order to solve the above-mentioned problems, a heat shield is provided according to the embodiment of the present invention, which can effectively optimize the thermal compensation effect at the bottom of the crystal by modifying the structure of the heat shield, thereby improving crystal pulling efficiency and growth quality of the crystal.

In particular, refer to FIG. 1, which is a schematic diagram showing working environment of a heat shield according to the embodiment of the present invention. It should be noted that the illustrations provided in this embodiment only illustrate the basic idea of the present invention in a schematic manner, so that the illustrations only show components related to the present invention rather than the numbers, shapes and dimensions of the components in actual implementation. The shape, number, and dimension of each component can be changed randomly in actual implementation, and layouts of the components may also be more complex.

The heat shield 1 is arranged in an upper portion of a melt crucible in a monocrystalline silicon growth furnace. The heat shield 1 can be divided into a shield wall 11 and a shield bottom 12. The shield wall 11 is connected to the monocrystalline silicon growth furnace, specifically the shield wall 11 is fixed to a furnace wall of the monocrystalline silicon growth furnace.

In the embodiment of the present invention, the shield wall 11 may be designed as a single layer, may be directly attached to the furnace wall of the monocrystalline silicon growth furnace, or may be configured to form a certain angle with the furnace wall, so that the shield wall 11 can carry the thermal energy from the melt, which avoids thermal energy from spreading from bottom to an upper part of the monocrystalline silicon growth furnace and ensures the longitudinal temperature gradient of the crystal. Specifically, the shield wall 11 may be a single graphite layer, and the graphite layer has a heat reflection system which can be set according to different requirements.

In some other embodiments, the shield wall 11 may also be designed as a two-layer structure, with a heat insulating material filled between the two layers. Preferably, an upper layer and a lower layer of the shield wall 11 may be provided with graphite layers with different reflection coefficients. The upper graphite layer of the shield wall 11 can carry thermal energy to prevent the thermal energy from reaching the upper part of the monocrystalline silicon growth furnace. The lower graphite layer of the shield wall 11 is used to reflect the thermal energy of the melt. The specific reflection coefficients of the upper and lower graphite layers are not specifically limited here.

In the embodiment of the present invention, the shield bottom 12 is connected with the shield wall 11 and may comprise a top layer 121, a bottom layer 122 and a side wall 123. When the shield wall 11 is a single-layer structure, the top layer 121, the bottom layer 122 and the side wall 123 enclose an internal space. The distance between the top layer 121 and the lower city 122 is not limited, alternatively, it may be in a range from 300 mm to 500 mm. The internal space is filled with a heat insulating material to maintain the temperature of the shield bottom 12, which can provide a better longitudinal temperature gradient during the crystal pulling process. Alternatively, the internal space may be filled with carbon fiber felt.

In some other embodiments, when the shield wall 11 is a two-layer structure, the internal space enclosed by the top layer 121, the bottom layer 122, and the side wall 123 is communicated with an internal space of the shield wall 11, so that the communicated space may be filled with a heat insulating material to prevent thermal energy from spreading upward.

On the other hand, the top layer 121 and the bottom layer 122 each may be a graphite layer, and the side wall 123 may also be a graphite layer. The graphite layers of the top layer 121, the bottom layer 122, and the side wall 123 may have different heat reflection coefficients.

In some other embodiments, the plane in which the top layer 121 is located is arranged to form a preset angle with the horizontal plane, and the plane in which the bottom layer 122 is located is arranged to be parallel to the horizontal plane. Alternatively, the preset angle may be in a range from 0° to 30°. In some other embodiments, the preset angle may be greater.

It should be noted that the shield wall 11 mainly functions to connect with the shield bottom 12 and prevent thermal energy of the melt from spreading upward. In practical applications, the shield wall 11 is designed as a circular-ring shape. The shield bottom in a circular-ring shape is connected under the shield wall 11 in a circular-ring shape. A window for pulling crystals through is provided in the middle of the shield bottom 12, that is, the window is enclosed by the side wall 123.

In the embodiment of the present invention, in order to avoid excessive heat compensation at the bottom of the crystal during the crystal pulling process, the bottom layer 122 may be designed as a serrated structure, so that the thermal energy from outside can be fully absorbed by the liquid level of the melt after being reflected by the surface of the bottom layer 122. When the heat compensation intensity of the sidewall of a lower part of the crystal is reduced, the lateral temperature gradient of the lower part of the crystal and the longitudinal temperature gradient of the entire crystal will be optimized simultaneously, which is beneficial to increase crystal pulling speed and crystal crystallization speed, and ultimately improving the quality of the silicon wafer.

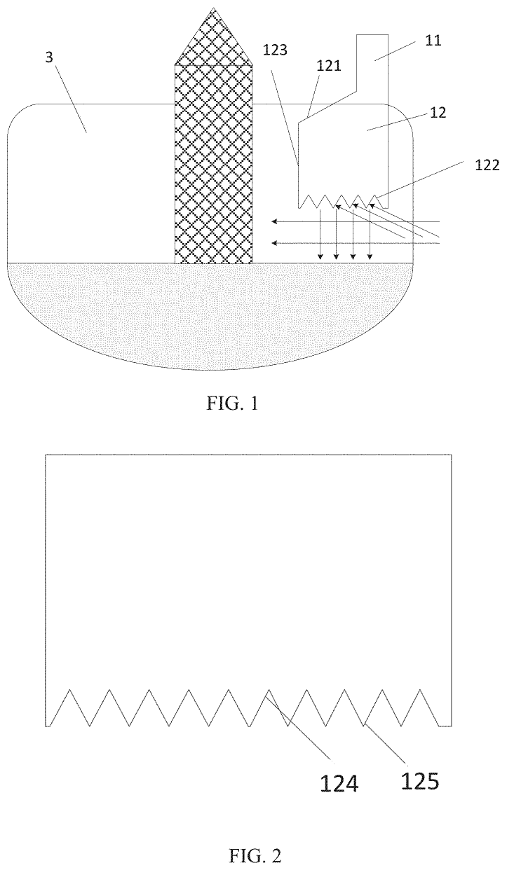

Specifically, refer to FIG. 2, which shows an embodiment of the present invention, the serrated structure may comprise a first row of serrations 124 and a second row of serrations 125. The first row of serrations 124 is arranged in a direction towards the top layer 121, and the second row of serrations 125 is arranged in a direction away from the top layer 121. The first row of serrations 124 comprises a plurality of first serrations, and the second row of serrations 125 comprises a plurality of second serrations.

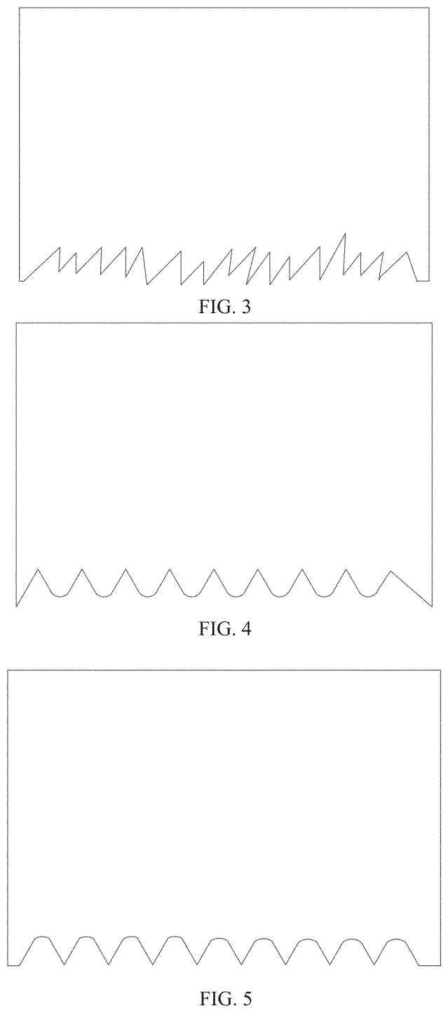

The plurality of first serrations may be the same or different. Accordingly, the second serrations may be the same or different. Specifically, refer to FIG. 3, a plurality of first angles may be different, and a plurality of second angles may also be different. Alternatively, the first angles and the second angles are equal.

It should be noted that the first angles can be configured such that their angle bisectors may be perpendicular to the liquid level of the melt. In some other embodiments, preferably, angle bisectors of the first angles may also be obliquely intersected with the liquid level of the melt. Specifically, angle bisectors of the first angles are arranged at acute angles with the liquid level of the melt, and openings of the acute angles are far away from the monocrystalline silicon crystal, such that the thermal energy from external sources, after being reflected by the bottom layer 12, can be absorbed directly by the liquid level of the melt, without being further reflected to side surfaces of the crystal. In this way, under the premise of ensuring the temperature of the liquid level, the temperature of the bottom surface of the crystal can be reduced, which improves the speed and efficiency of crystal pulling. On the other hand, the second angles can be configured such that their angle bisectors may be perpendicular to the melt surface. In some other embodiments, the angle bisectors of the second angles may also be obliquely intersected with the liquid level of the melt. The first angles and the second angles may be configured to have different angle values according to actual working conditions, such as the distance between the liquid level of the melt and the bottom layer, the size of the window, the size of the crystal, or the like. Preferably, the first angles may have a value in a range from 20° to 60°, and the second angles may have a value in a range from 20° to 60°.

In some other embodiments, the first angles and/or the second angles are provided with arcs for transition. Refer to FIGS. 4 to 6, which show other structural forms of the serrated structure. Specifically, as shown in FIG. 4, all the angles in the second row of serrations are provided with arcs for transition. When the second row of serrations is arranged at angles, the angles facing outwards will hurt a worker who is installing parts or replacing parts. Circular arcs serve to avoid injury to the worker.

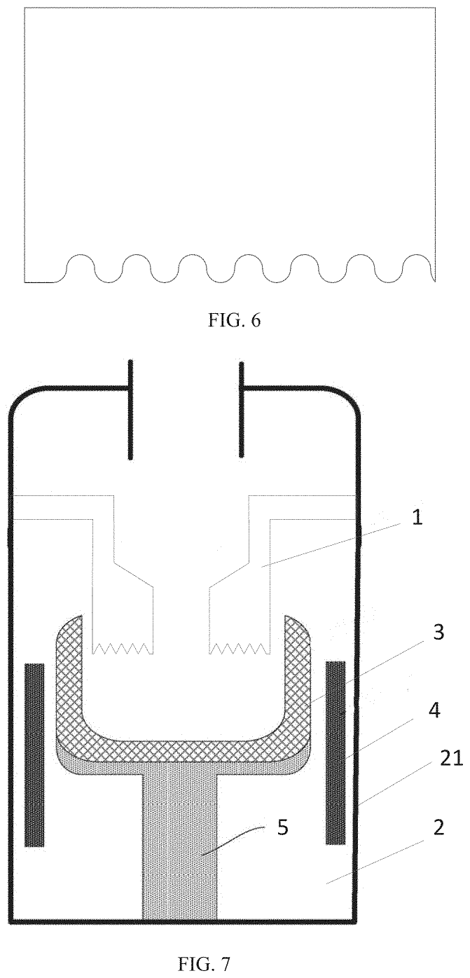

As shown in FIG. 5, the angles in the first row of serrations may are provided with arcs for transition, which may increase contact area of the bottom layer with the thermal energy. In other words, the thermal energy can be uniformly absorbed by the lower surface, thereby reducing reflected thermal energy. As shown in FIG. 6, the angles in the first row of serrations and the second row of serrations are provided with arcs for transition, so that the thermal energy from outside and the melt can be received more comprehensively and absorbed uniformly, which can reduce reflected thermal energy. It should be noted that, as shown in FIGS. 4 and 5, only some angles are provided with arcs for transition to form different serrated structures, which will not be repeated here.

It should be noted that the numbers and sizes of the first serrations and the second serrations of the serrated structure are also not limited, and can be adjusted according to operating environment of customers or users and the temperature gradients. Preferably, the serrated structure completely covers the bottom layer 122, each of the first tooth and the second tooth has a length of 50 mm. In some other embodiments, the first tooth and the second tooth may also have different sizes.

Based on the aforementioned head shield, a device in which the heat shield is applied is also provided. In other words, a monocrystalline silicon growth furnace is also provided according to an embodiment of the present invention. Refer to FIG. 7, the monocrystalline silicon growth furnace comprises:

a furnace body comprising a furnace body wall and a cavity surrounded by the furnace body wall;

a melt crucible disposed in the cavity and suitable for containing melt;

a heater disposed in the cavity and around the melt crucible to provide a thermal field for the melt crucible; and

a heat shield provided above.

The heat shield is arranged in an upper portion of the melt crucible 3 to provide temperature gradients required for crystallization of the monocrystalline silicon. A rotating shaft 5 is also connected to the bottom of the melt crucible 3, by which the melt crucible 3 is controlled to rise and rotate, which can ensure stability of thermal energy of the melt and improve heating uniformity of the melt.

With the heat shield and the monocrystalline silicon growth furnace, the following beneficial effects can be achieved:

(1) In the heat shield and the monocrystalline silicon growth furnace according to the present invention, the bottom layer of the shield bottom is designed as a serrated structure, which can prevent external thermal energy from being absorbed by the monocrystalline silicon crystal, thereby avoiding excessive thermal compensation on the crystal surface, effectively optimizing the longitudinal temperature gradient of the crystal, and improving the radial quality uniformity of a silicon wafer.

(2) In the heat shield and the monocrystalline silicon growth furnace according to the present invention, the bottom layer of the shield bottom is designed as a serrated structure, which can reflect the external thermal energy into the melt so as to be absorbed by the melt, thereby avoiding a temperature of the melt liquid level to fall too fast, ensuring melting state of the melt, and improving effects of crystal pulling.

(3) The heat shield and the monocrystalline silicon growth furnace according to the present invention can effectively improve process effects by modifying the structure of the shield bottom, and have a better application prospect in the field of semiconductor manufacturing.

The above-mentioned embodiments are preferred embodiments of the present invention, and are not intended to limit the present invention. It is apparent that to those skilled in the art that the present invention is not limited to the exemplary embodiments and can be implemented in other specific forms without departing from the spirit or essential features of the present invention. Therefore, from any point of view, the embodiments should be regarded as exemplary and non-limiting. All equivalent changes and modifications made in accordance with the present invention fall within the scope of the present invention defined by the attached claims. Any reference signs in the claims should not be regarded as limiting the claims involved.

In addition, it should be understood that although the specification is described in accordance with embodiments, not each embodiment only includes an independent technical solution. The specification is described in this way only for clarity, the specification should be regard as a whole by those skilled in the art. The technical solutions in each embodiment can also be appropriately combined to form other implementations that can be understood by those skilled in the art.

1. A heat shield for a monocrystalline silicon growth furnace comprising a melt crucible, wherein the heat shield (1) is arranged in an upper portion of the melt crucible, and comprises a shield wall (11) and a shield bottom (12) provided with a window for pulling melt through; the shield bottom (12) comprises a top layer (121), a bottom layer (122) and a side wall (123); the side wall (123) is connected between the top layer (121) and the bottom layer (122) and encloses the window; the bottom layer (122) faces towards a liquid level of the melt, and is designed as a serrated structure to prevent external thermal energy from being reflected to a sidewall of a monocrystalline silicon crystal.

2. The heat shield of claim 1, wherein a plane where the bottom layer (122) is located is arranged to be parallel to the liquid level of the melt.

3. The heat shield of claim 1, wherein the serrated structure comprises a first row of serrations (124) and a second row of serrations (125), the first row of serrations (124) is arranged in a direction towards the top layer (121) and the second row of serrations (125) is arranged in a direction away from the top layer (121), the first row of serrations (124) comprises a plurality of first serrations arranged at first angles, the second row of serrations (125) comprises a plurality of second serrations arranged at second angles, and the first serrations and the second serrations are arranged alternately in sequence.

4. The heat shield of claim 3, wherein a plurality of the first angles are not all the same, and a plurality of the second angles are not all the same.

5. The heat shield of claim 3, wherein angular bisectors of the first angles are arranged to form acute angles with the liquid level of the melt, and openings of the acute angles are far away from the monocrystalline silicon crystal.

6. The heat shield of claim 3, wherein the first angles and/or the second angles are provided with arcs for transition.

7. The heat shield of claim 1, wherein the top layer (121), the bottom layer (122) and the side wall (123) enclose an inner space of the shield bottom (12), which is filled with a heat insulating material.

8. The heat shield of claim 7, wherein the heat insulating material comprises carbon fiber felt.

9. The heat shield of claim 1, wherein the top layer (121) and the bottom layer (122) are each provided with a graphite layer.

10. A monocrystalline silicon growth furnace, wherein the monocrystalline silicon growth furnace comprises:
a furnace body (2) comprising a furnace body wall (21) and a cavity surrounded by the furnace body wall (21);
a melt crucible (3) arranged in the cavity and suitable for containing melt;
a heater (4) disposed in the cavity and around the melt crucible (3) to provide a thermal field for the melt crucible (3); and
a heat shield for a monocrystalline silicon growth furnace of claim 1.

11. A monocrystalline silicon growth furnace, wherein the growth furnace comprises:
a furnace body (2) comprising a furnace body wall (21) and a cavity surrounded by the furnace body wall (21);
a melt crucible (3) arranged in the cavity and suitable for containing melt;
a heater (4) disposed in the cavity and around the melt crucible (3) to provide a thermal field for the melt crucible (3); and
a heat shield for a monocrystalline silicon growth furnace of claim 2.

12. A monocrystalline silicon growth furnace, wherein the monocrystalline silicon growth furnace comprises:
a furnace body (2) comprising a furnace body wall (21) and a cavity surrounded by the furnace body wall (21);
a melt crucible (3) arranged in the cavity and suitable for containing melt;
a heater (4) disposed in the cavity and around the melt crucible (3) to provide a thermal field for the melt crucible (3); and
a heat shield for a monocrystalline silicon growth furnace of claim 3.

13. A monocrystalline silicon growth furnace, wherein the monocrystalline silicon growth furnace comprises:
a furnace body (2) comprising a furnace body wall (21) and a cavity surrounded by the furnace body wall (21);
a melt crucible (3) arranged in the cavity and suitable for containing melt;
a heater (4) disposed in the cavity and around the melt crucible (3) to provide a thermal field for the melt crucible (3); and
a heat shield for a monocrystalline silicon growth furnace of claim 4.

14. A monocrystalline silicon growth furnace, wherein the monocrystalline silicon growth furnace comprises:
a furnace body (2) comprising a furnace body wall (21) and a cavity surrounded by the furnace body wall (21);
a melt crucible (3) arranged in the cavity and suitable for containing melt;
a heater (4) disposed in the cavity and around the melt crucible (3) to provide a thermal field for the melt crucible (3); and
a heat shield for a monocrystalline silicon growth furnace of claim 5.

15. A monocrystalline silicon growth furnace, wherein the monocrystalline silicon growth furnace comprises:
a furnace body (2) comprising a furnace body wall (21) and a cavity surrounded by the furnace body wall (21);
a melt crucible (3) arranged in the cavity and suitable for containing melt;
a heater (4) disposed in the cavity and around the melt crucible (3) to provide a thermal field for the melt crucible (3); and
a heat shield for a monocrystalline silicon growth furnace of claim 6.

16. A monocrystalline silicon growth furnace, wherein the monocrystalline silicon growth furnace comprises:
a furnace body (2) comprising a furnace body wall (21) and a cavity surrounded by the furnace body wall (21);
a melt crucible (3) arranged in the cavity and suitable for containing melt;
a heater (4) disposed in the cavity and around the melt crucible (3) to provide a thermal field for the melt crucible (3); and
a heat shield for a monocrystalline silicon growth furnace of claim 7.

17. A monocrystalline silicon growth furnace, wherein the monocrystalline silicon growth furnace comprises:
a furnace body (2) comprising a furnace body wall (21) and a cavity surrounded by the furnace body wall (21);
a melt crucible (3) arranged in the cavity and suitable for containing melt;
a heater (4) disposed in the cavity and around the melt crucible (3) to provide a thermal field for the melt crucible (3); and
a heat shield for a monocrystalline silicon growth furnace of claim 8.

18. A monocrystalline silicon growth furnace, wherein the monocrystalline silicon growth furnace comprises:
a furnace body (2) comprising a furnace body wall (21) and a cavity surrounded by the furnace body wall (21);
a melt crucible (3) arranged in the cavity and suitable for containing melt;
a heater (4) disposed in the cavity and around the melt crucible (3) to provide a thermal field for the melt crucible (3); and
a heat shield for a monocrystalline silicon growth furnace of claim 9.
